(19) United States
(12) Patent Application Publication
(10) Pub. No.: US 2025/0266105 A1
(43) Pub. Date: Aug. 21, 2025

(54) MEMORY DEVICE, STORAGE AREA OF THE SAME, AND OPERATING METHOD OF MEMORY DEVICE

(71) Applicant: SAMSUNG ELECTRONICS CO., LTD., Suwon-si (KR)

(72) Inventors: Junghwan Kwak, Suwon-si (KR); Jungmin Seo, Suwon-si (KR); Yeonwook Jung, Suwon-si (KR)

(73) Assignee: SAMSUNG ELECTRONICS CO., LTD., Suwon-si (KR)

(21) Appl. No.: 18/999,605

(22) Filed: Dec. 23, 2024

(30) Foreign Application Priority Data
Feb. 16, 2024 (KR) 10-2024-0022811

(51) Int. Cl. G11C 16/28; G11C 16/12

(52) U.S. Cl. CPC G11C 16/28; G11C 16/12; G11C 2207/2254

(57) ABSTRACT

A memory device performing ZQ calibration by calibrating a voltage level of a data signal includes a memory controller configured to generate the data signal, a plurality of channels configured to transmit the data signal, and a plurality of storage areas configured to receive the data signal, wherein each of the plurality of storage areas includes an input pin configured to receive the data signal, and a loop circuit configured to compare the voltage level of the data signal with a preset reference voltage level and, based on a result of the comparison, calibrate the voltage level of the data signal such that a difference between the voltage level of the data signal and the preset reference voltage level has a preset reference value.

### CROSS-REFERENCE TO RELATED APPLICATION

This application is based on and claims priority to Korean Patent Application No. 10-2024-0022811, filed on Feb. 16, 2024, in the Korean Intellectual Property Office, the disclosure of which is incorporated by reference herein in its entirety.

### BACKGROUND

### 1. Field

The disclosure relates to a memory device, a storage area of the same, and an operating method of the memory device, and more particularly, to a memory device capable of calibrating an offset of a voltage level of a data signal with respect to a reference value by calibrating the voltage level of the data signal.

### 2. Description of Related Art

When a write operation or a read operation is performed in a memory device, transmission of a data signal is performed. The data signal may be transmitted at a certain voltage level. Due to internal resistance of the memory device, noise may occur in the voltage level of the data signal.

To compensate for the noise occurring in the voltage level of the data signal, a technique of calibrating the voltage level of the data signal is required. However, because the data signal is transmitted to a plurality of storage areas through a plurality of channels, respectively, the degree of noise occurring in the data signal may be different from one channel to the next. Accordingly, techniques for independently calibrating the voltage level of a data signal for each channel and storage area, to which the data signal is transmitted, are desired.

### SUMMARY

Provided is a memory device capable of independently calibrating the voltage level of a data signal for each channel and storage area of the device to which the data signal is transmitted.

Further provided is a memory device capable of calibrating the voltage level of a data signal by using a certain reference value.

According to an aspect of the disclosure, a memory device includes: a memory controller configured to generate a data signal; a channel configured to transmit the data signal; and a storage area configured to receive the data signal, wherein the storage area includes: an input pin configured to receive the data signal; and a loop circuit configured to: compare a voltage level of the data signal with a preset reference voltage level, and calibrate, based on a result of the comparison of the voltage level of the data signal and the preset reference voltage level, the voltage level of the data signal such that a difference between the voltage level of the data signal and the preset reference voltage level has a preset reference value.

According to an aspect of the disclosure, an method of operating a memory device includes: generating, by a memory controller of the memory device, a data signal; transmitting the data signal through a channel of the memory device; and receiving, by a storage area of the memory device, the data signal, wherein the receiving the data signal includes: comparing a voltage level of the data signal with a preset reference voltage level; and calibrating, based on a result of the comparison of the voltage level of the data signal and the preset reference voltage level, the voltage level of the data signal such that a difference between the voltage level of the data signal and the preset reference voltage level has a preset reference value.

According to an aspect of the disclosure, a memory device includes: a storage area, the storage area including: an input pin configured to receive a data signal; and a loop circuit configured to: compare a voltage level of the data signal and a preset reference voltage level, and calibrate, based on a result of the comparison of the voltage level of the data signal and the present reference voltage, the voltage level of the data signal such that a difference between the voltage level of the data signal and the preset reference voltage level has a preset reference value.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of a memory device according to an embodiment;

FIG. 2 is a block diagram of a storage area according to an embodiment;

FIG. 3 is a block diagram of a loop circuit according to an embodiment;

FIG. 4 is a diagram illustrating a circuit of a memory device, according to an embodiment;

FIG. 5 is a diagram illustrating the configuration of a counter circuit according to an embodiment;

FIG. 6 is a diagram illustrating a result of performing offset calibration on a data signal, according to an embodiment;

FIG. 7 is a flowchart of an operating method of a memory device, according to an embodiment;

FIGS. 8 and 9 are flowcharts of processes of performing offset calibration on a data signal in an operating method of a memory device, according to one or more embodiments; and

FIGS. 10, 11 and 12 are diagrams illustrating a three-dimensional (3D) vertical NAND (VNAND) structure applicable to a memory device, according to an embodiment.

### DETAILED DESCRIPTION

Hereinafter, embodiments are described with reference to the accompanying drawings. For clear understanding, detailed descriptions of configurations and structures are provided. Various changes and modifications may be made in embodiments described herein without departing from the scope of the disclosure.

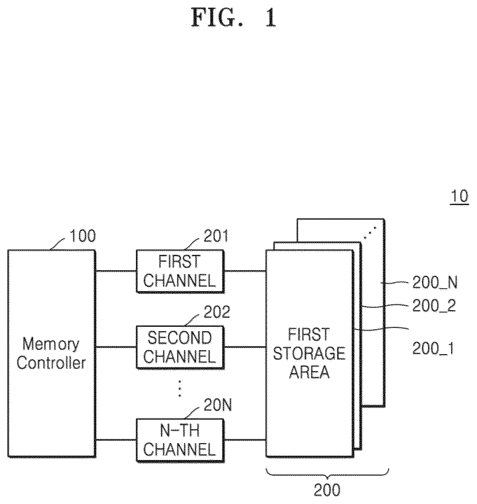

FIG. 1 is a block diagram of a memory device according to an embodiment.

Referring to FIG. 1, according to an embodiment, a memory device 10 may include a memory controller 100, a storage area 200, and a plurality of channels (e.g., 201 to 20N). The memory device 10 may perform ZQ calibration by calibrating a voltage level of a data signal.

According to an embodiment, the memory controller 100 may generate a data signal. For example, the memory controller 100 may generate a plurality of data signals for the storage area 200 and transmit the data signals to the storage area 200 through channels respectively corresponding to the data signals. According to an embodiment, a data signal may be generated in correspondence with a channel. For example, data signals may be generated in correspondence with <0:7> channels but are not limited thereto.

According to an embodiment, the storage area 200 may include a plurality of storage areas (e.g., 200_1 to 200_N). For example, each of the storage areas (200_1 to 200_N) may be configured to independently receive a data signal. According to an embodiment, each of the storage areas (200_1 to 200_N) may receive a data signal, compare the voltage level of the data with a preset reference voltage level, and calibrate the voltage level of the data signal based on a result of the comparison such that the difference between the voltage level of the data signal and the reference voltage level has a preset reference value. According to an embodiment, the preset reference value may be determined at the time when the memory device 10 is manufactured but it not limited thereto. The preset reference value may be changed by a user while the user is using the memory device 10. According to an embodiment, the storage areas (200_1 to 200_N) may be configured to respectively correspond to the channels (201 to 20N) and each may receive a data signal through its corresponding channel.

According to an embodiment, the channels (201 to 20N) may transmit data signals. For example, each of the channels (201 to 20N) may transmit a data signal from the memory controller 100 to the storage area 200 designated for the data signal. For example, a first channel 201 corresponding to a first data signal may transmit the first data signal to a first storage area 200_1. According to an embodiment, the number of channels (201 to 20N) may be determined according to a mode of a data signal that is generated. For example, when a data signal mode is a <0:7> mode, the number of channels (201 to 20N) may be determined to transmit data signals in the <0:7> mode.

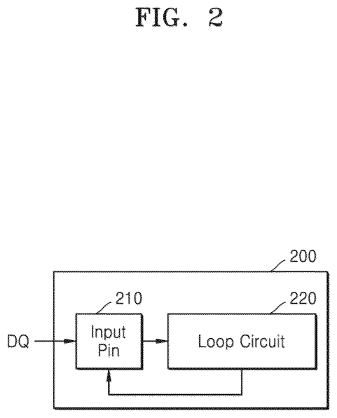

FIG. 2 is a block diagram of the storage area 200 according to an embodiment.

Referring to FIGS. 1 and 2, the storage area 200 may include an input pin 210 and a loop circuit 220. Although the embodiment of FIG. 2 is described based on one storage area 200, each of the storage areas (200_1 to 200_N) in the embodiment of FIG. 1 may include the same configuration as the storage area 200 of FIG. 2.

According to an embodiment, the input pin 210 may receive a data signal DQ in correspondence with each of a plurality of channels. For example, the memory controller 100 may generate the data signal DQ and transmit the data signal DQ to a channel corresponding to the data signal DQ. According to an embodiment, the input pin 210 may receive the data signal DQ through corresponding one of the channels (201 to 20N) and transmit the data signal DQ to the loop circuit 220. For example, when the data signal DQ corresponds to the first channel 201, the input pin 210 may receive the data signal DQ through the first channel 201 and transmit the data signal DQ to the loop circuit 220. According to an embodiment, the storage area 200 corresponding to the first channel 201 may be the first storage area 200_1. However, the term “first” or “second” is just used to distinguish the channels (201 to 20N) or the storage areas (200_1 to 200_N) from each other.

According to an embodiment, the loop circuit 220 may be configured to compare the voltage level of the data signal DQ with a preset reference voltage level and calibrate the voltage level of the data signal DQ based on a result of the comparison such that the difference between the voltage level of the data signal DQ and the reference voltage level has a preset reference value. According to an embodiment, the reference voltage level and the preset reference value may be determined at the time when the storage area 200 is manufactured. For example, when the difference between the voltage level of the data signal DQ and the reference voltage level is greater than the preset reference value, the loop circuit 220 may determine that offset calibration needs to be performed on the voltage level of the data signal DQ and may calibrate the voltage level of the data signal DQ so that the difference between the voltage level of the data signal DQ and the reference voltage level has the preset reference value.

According to an embodiment, the loop circuit 220 may be configured to calibrate the voltage level of each of the data signals DQ, which are respectively received through a plurality of input pins 210, for each storage area. For example, the loop circuit 220 may be mounted on each of the storage areas (200_1 to 200_N) and may calibrate the voltage level of one of the data signals DQ so that the difference between the voltage level of the data signal DQ and the reference voltage level has the preset reference value. According to an embodiment, the loop circuit 220 may be configured to perform calibration such that the difference between the voltage level of each of the data signals DQ respectively input to the input pins 210 and the reference voltage level is equal to the preset reference value. For example, the loop circuit 220 may calibrate the voltage level of a first data signal such that the difference between the voltage level of the first data signal input to the first storage area 200_1 and the reference voltage level has the preset reference value. The loop circuit 220 may also calibrate the voltage level of a second data signal such that the difference between the voltage level of the second data signal input to a second storage area 200_2 and the reference voltage level has the preset reference value. In other words, the memory device 10 may enable the difference between the voltage level of each of the data signals DQ, which are respectively input to the storage areas (200_1 to 200_N), and the reference voltage level to be equal to the preset reference value through the loop circuit 220, thereby matching voltage levels, which are recognized as logic high, with respect to the storage areas (200_1 to 200_N).

According to an embodiment, the loop circuit 220 may receive the data signal DQ, calibrate the voltage level of the data signal DQ, and then transmit a calibrated data signal to the input pin 210. For example, the loop circuit 220 may perform calibration based on a reference voltage information signal received from the memory controller 100 such that the difference between the voltage level of the data signal DQ and the reference voltage level is equal to the preset reference value. According to an embodiment, the loop circuit 220 may perform a feedback operation according to voltage level calibration by transmitting a voltage-level calibrated data signal to the input pin 210. For example, when voltage level calibration on the data signal DQ is not completely performed by the loop circuit 220, the loop circuit 220 may newly calibrate the voltage level of the data signal DQ. In other words, when the difference between the voltage level of the data signal DQ and the reference voltage level is not equal to the preset reference value after first calibration is performed on the voltage level of the data signal DQ, the loop circuit 220 may perform second calibration on the voltage level of the data signal DQ.

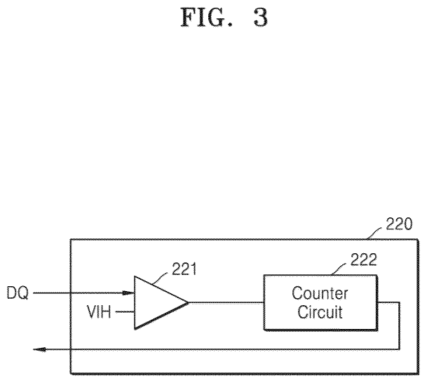

FIG. 3 is a block diagram of the loop circuit 220 according to an embodiment.

Referring to FIGS. 1 to 3, the loop circuit 220 may include a comparator 221 and a counter circuit 222.

According to an embodiment, the comparator 221 may compare a preset reference value VIH with the voltage of the data signal DQ. For example, the comparator 221 may receive the preset reference value VIH as a preset value and determine whether the voltage level of the data signal DQ is equal to the preset reference value VIH. When it is determined that the voltage level of the data signal DQ is equal to the preset reference value VIH, the comparator 221 may stop the operation of comparing the preset reference value VIH with the voltage level of the data signal DQ. According to an embodiment, when the voltage level of the data signal DQ has the preset reference value VIH, the memory device 10 may maintain the voltage level of the data signal DQ constant and determine the voltage level, which is determined to be logic high, to be one value. According to an embodiment, the preset reference value VIH may correspond to a voltage level determined as logic high.

According to an embodiment, the counter circuit 222 may calibrate the voltage of the data signal DQ such that the difference between the voltage of the data signal DQ and a reference voltage has the preset reference value VIH.

According to an embodiment, the counter circuit 222 may perform a feedback operation according to voltage level calibration. For example, when the voltage level calibration on the data signal DQ by the counter circuit 222 is not completely performed, the counter circuit 222 may newly calibrate the voltage level of the data signal DQ. In other words, when the difference between the voltage level of the data signal DQ and the reference voltage level is not equal to the preset reference value VIH after first calibration is performed on the voltage level of the data signal DQ, the counter circuit 222 may perform second calibration on the voltage level of the data signal DQ.

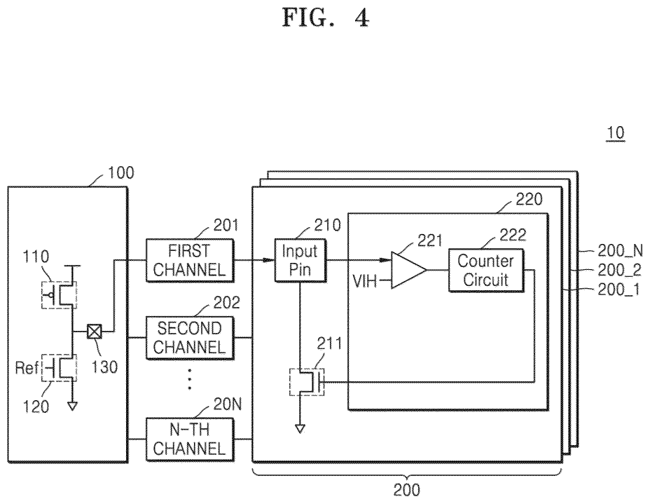

FIG. 4 is a diagram illustrating a circuit of the memory device 10, according to an embodiment.

Referring to FIGS. 1 to 4, the memory controller 100 may include a first transistor 110, a second transistor 120, and an output terminal 130.

According to an embodiment, the first transistor 110 may have a certain resistance value for transmission of a reference voltage signal Ref. For example, the first transistor 110 may have a certain variable resistance value for transmitting the reference voltage signal Ref to the storage area 200.

According to an embodiment, the second transistor 120 may correspond to a switch that allows the reference voltage signal Ref to be transmitted to the storage area 200. For example, the second transistor 120 may receive the reference voltage signal Ref and transmit the reference voltage signal Ref to the storage area 200 at a preset interval. According to an embodiment, the preset interval may be determined according to a transmission period of the data signal DQ. For example, the reference voltage signal Ref may be transmitted whenever the data signal DQ is transmitted.

According to an embodiment, the output terminal 130 may transmit the data signal DQ and the reference voltage signal Ref to a channel corresponding to the data signal DQ. For example, the output terminal 130 may transmit the first data signal to the first channel 201. The output terminal 130 may also transmit a second data signal to a second channel 202. According to an embodiment, the output terminal 130 may independently transmit the reference voltage signal Ref and the data signal DQ to each of N channels. According to an embodiment, the output terminal 130 may include an output pin or an output pad but is not limited thereto. The output terminal 130 may be replaced with any configuration that may transmit the reference voltage signal Ref and the data signal DQ.

According to an embodiment, the storage area 200 may include a plurality of storage areas (e.g., 200_1 to 200_N). For example, the storage areas (200_1 to 200_N) may each be configured to independently receive a data signal. According to an embodiment, each of the storage areas (200_1 to 200_N) may receive a data signal, compare the voltage level of the data signal with a preset reference voltage level, and calibrate the voltage level of the data signal based on a result of the comparison such that the difference between the voltage level of the data signal and the reference voltage level has a preset reference value. According to an embodiment, the preset reference value may be determined at the time when the memory device 10 is manufactured but it not limited thereto. The preset reference value may be changed by a user while the user is using the memory device 10.

According to an embodiment, each of the storage areas (200_1 to 200_N) may include the input pin 210 and the loop circuit 220. For example, each of the storage areas (200_1 to 200_N) may independently receive the data signal DQ through the input pin 210, and the loop circuit 220 of each storage area may calibrate the voltage level of the data signal DQ. For example, the loop circuit 220 may include the comparator 221 and the counter circuit 222 and may compare the preset reference value VIH with the voltage of the data signal DQ and calibrate the voltage level of the data signal DQ.

According to an embodiment, the loop circuit 220 may perform a feedback operation through the counter circuit 222 with respect to the voltage level calibration on the data signal DQ. For example, the voltage level calibration on the data signal DQ by the counter circuit 222 is not completely performed, the counter circuit 222 may newly calibrate the voltage level of the data signal DQ. In other words, when the difference between the voltage level of the data signal DQ and the reference voltage level is not equal to the preset reference value VIH after first calibration is performed on the voltage level of the data signal DQ, the counter circuit 222 may perform second calibration on the voltage level of the data signal DQ.

According to an embodiment, each of the storage areas (200_1 to 200_N) may further include a third transistor 211. According to an embodiment, the third transistor 211 may correspond to a switch for performing the feedback operation with respect to the calibration on the data signal DQ. For example, the third transistor 211 may transmit the data signal DQ having a calibrated voltage level to the comparator 221 by transmitting the data signal DQ having the calibrated voltage level to the input pin 210. According to an embodiment, the comparator 221 may determine whether the data signal DQ having the calibrated voltage level has the preset reference value VIH. When it is determined that the data signal DQ having the calibrated voltage level has the preset reference value VIH, the comparator 221 may stop voltage level calibration of the data signal DQ.

According to an embodiment, the storage areas (200_1 to 200_N) may be configured in respective correspondence with the channels (201 to 20N) and each may receive a data signal through its corresponding channel. According to an embodiment, each of the channels (201 to 20N) may transmit the data signal. For example, each of the channels (201 to 20N) may transmit a data signal corresponding thereto from the memory controller 100 to the storage area 200 designated for the data signal. For example, the first channel 201 corresponding to the first data signal may transmit the first data signal to the first storage area 200_1. According to an embodiment, the number of channels (201 to 20N) may be determined according to a mode of a data signal that is generated. For example, when a data signal mode is a <0:7> mode, the number of channels (201 to 20N) may be determined to transmit data signals in the <0:7> mode.

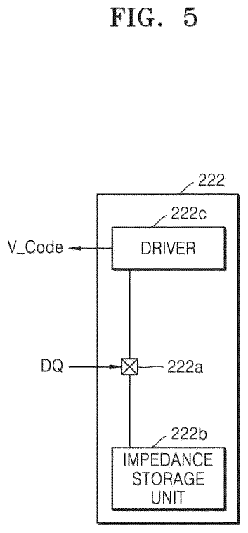

FIG. 5 is a diagram illustrating the configuration of the counter circuit 222 according to an embodiment.

Referring to FIGS. 3 and 5, according to an embodiment, the counter circuit 222 may include an input pad 222a, an impedance storage unit 222b, and a driver 222c.

According to an embodiment, the input pad 222a may receive the data signal DQ. For example, the input pad 222a may receive the data signal DQ output from the comparator 221. According to an embodiment, the data signal DQ may be output when the data signal DQ has a voltage level that is greater than the preset reference value VIH. For example, when the voltage level of the data signal DQ has a value that is greater than the preset reference value VIH, the comparator 221 may output the data signal DQ, and the input pad 222a of the counter circuit 222 may receive the data signal DQ and enable calibration of the voltage level of the data signal DQ to be performed.

According to an embodiment, the impedance storage unit 222b may store a preset impedance value. According to an embodiment, the impedance storage unit 222b may store a preset impedance value and calibrate the voltage level of the data signal DQ. For example, the impedance storage unit 222b may receive the data signal DQ and calibrate the voltage level of the data signal DQ based on the preset impedance value. For example, the impedance storage unit 222b may perform voltage level drop calibration on the data signal DQ by using impedance, such that the voltage level of the data signal DQ has the preset reference value VIH. The impedance storage unit 222b may also perform voltage level rise calibration on the data signal DQ by using impedance, such that the voltage level of the data signal DQ has the preset reference value VIH.

According to an embodiment, the driver 222c may transmit a code V_Code, which has voltage information of the data signal DQ that has been calibrated based on the preset impedance value, to the comparator 221. For example, the driver 222c may generate the code V_Code, which includes the voltage information of the data signal DQ of which the voltage level has been calibrated, and transmit the code V_Code to the comparator 221 to allow the comparator 221 to determine whether to perform second calibration on the data signal DQ. For example, when the voltage information included in the code V_Code received from the driver 222c is information indicating that the voltage level calibration of the data signal DQ has not been completely performed, the counter circuit 222 may newly calibrate the voltage level of the data signal DQ. In other words, when the difference between the voltage level of the data signal DQ and the reference voltage level is not equal to the preset reference value VIH after first calibration is performed on the voltage level of the data signal DQ, the counter circuit 222 may perform second calibration on the voltage level of the data signal DQ.

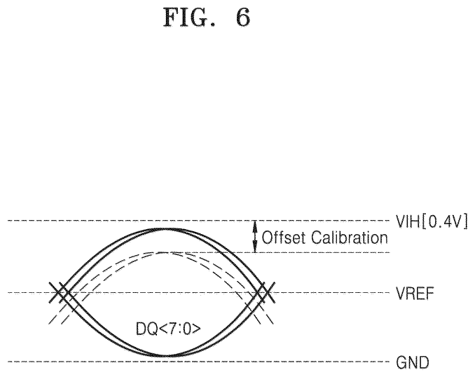

FIG. 6 is a diagram illustrating a result of performing offset calibration on a data signal, according to an embodiment.

Referring to FIGS. 1, 2, and 6, according to an embodiment, the voltage level of the data signal DQ may be calibrated to have a ground value GND as a minimum limit and the preset reference value VIH as a maximum limit. For example, the voltage level of the data signal DQ may be calibrated to have a symmetrical value with respect to a reference voltage VREF. According to an embodiment, the voltage level of the data signal DQ may drop due to noise when the data signal DQ is transmitted from the memory controller 100 to the storage area 200. According to an embodiment, the memory device 10 may perform offset calibration on the data signal DQ by calibrating the voltage level of the data signal DQ to the preset reference value VIH.

According to an embodiment, the memory device 10 may compare the preset reference value VIH with the voltage of the data signal DQ. For example, the memory device 10 may determine whether the voltage level of the data signal DQ has the preset reference value VIH. When it is determine that the voltage level of the data signal DQ has the preset reference value VIH, the memory device 10 may stop the operation of comparing the voltage level of the data signal DQ with the preset reference value VIH. According to an embodiment, when the voltage level of the data signal DQ has the preset reference value VIH, the memory device 10 may maintain the voltage level of the data signal DQ constant and determine the voltage level, which is determined to be logic high, to be one value. According to an embodiment, the preset reference value VIH may correspond to a voltage level determined as logic high.

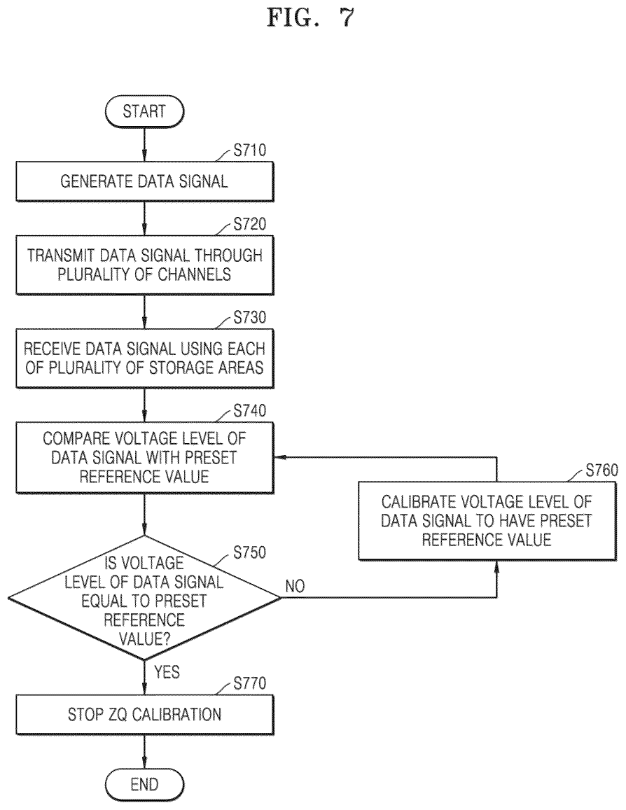

FIG. 7 is a flowchart of an operating method of the memory device 10, according to an embodiment.

Referring to FIGS. 1, 2, and 7, according to an embodiment, the memory device 10 may generate a data signal DQ in operation S710.

When the data signal DQ is generated, the memory device 10 may transmit the data signal DQ through a plurality of channels (e.g., 201 to 20N) in operation S720.

According to an embodiment, the channels (201 to 20N) may each transmit a data signal. For example, each of the channels (201 to 20N) may transmit a data signal corresponding thereto from the memory controller 100 to the storage area 200 designated for the data signal. For example, the first channel 201 corresponding to a first data signal may transmit the first data signal to the first storage area 200_1. According to an embodiment, the number of channels (201 to 20N) may be determined according to a mode of a data signal that is generated. For example, when a data signal mode is a <0:7> mode, the number of channels (201 to 20N) may be determined to transmit data signals in the <0:7> mode.

When the data signal DQ is transmitted to each of a plurality of storage areas (e.g., 200_1 to 200_N) through one of the channels (201 to 20N), each of the storage areas (200_1 to 200_N) of the memory device 10 may receive the data signal DQ in operation S730. According to an embodiment, the storage area 200 may include a plurality of storage areas (e.g., 200_1 to 200_N). For example, each of the storage areas (200_1 to 200_N) may be configured to independently receive a data signal.

When the data signal DQ is received by each of the storage areas (200_1 to 200_N), the memory device 10 may compare the voltage level of the data signal DQ with a preset reference value in operation S740.

According to an embodiment, the memory device 10 may determine whether the voltage level of the data signal DQ is equal to the preset reference value in operation S750.

According to an embodiment, the memory device 10 may compare the preset reference value with the voltage of the data signal DQ. For example, the memory device 10 may receive the preset reference value as a set value and determine whether the voltage level of the data signal DQ is equal to the preset reference value.

When it is determined that the voltage level of the data signal DQ is not equal to the preset reference value, the memory device 10 may calibrate the voltage level of the data signal DQ to have the preset reference value in operation S760.

According to an embodiment, when the voltage level of the data signal DQ has the preset reference value, the memory device 10 may maintain the voltage level of the data signal DQ constant and determine a voltage level, which is determined as logic high, as a single value. According to an embodiment, the preset reference value (e.g., VIH) may correspond to a voltage level determined as logic high.

Otherwise, when it is determined that the voltage level of the data signal DQ is equal to the preset reference value, the memory device 10 may stop ZQ calibration in operation S770. According to an embodiment, the ZQ calibration may include an operation of calibrating an offset of the data signal DQ with respect to the preset reference value by calibrating the voltage level of the data signal DQ.

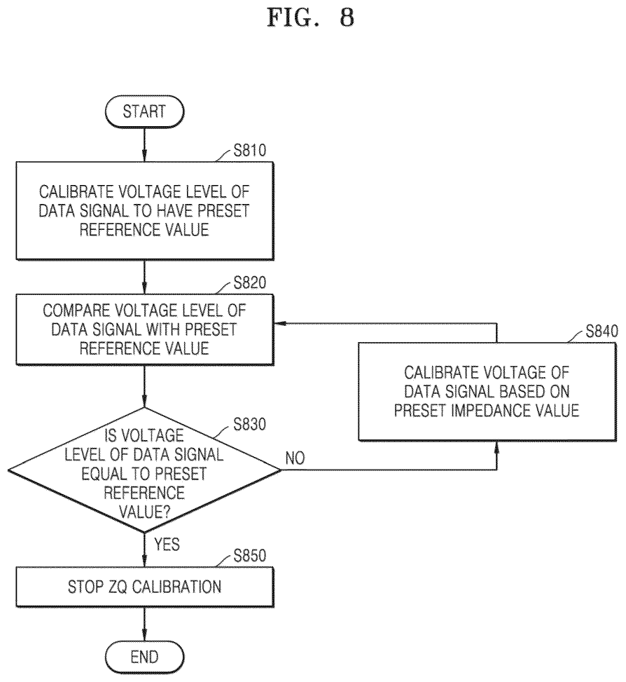

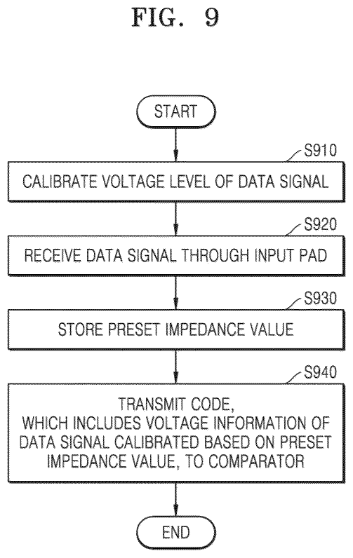

FIGS. 8 and 9 are flowcharts of processes of performing offset calibration on a data signal in an operating method of the memory device 10, according to embodiments.

FIG. 8 is a flowchart of a feedback operation of the memory device 10 with respect to the calibration of the voltage level of the data signal DQ, according to an embodiment.

Referring to FIGS. 1, 2, and 8, according to an embodiment, the memory device 10 may calibrate the voltage level of the data signal DQ to have a preset reference value in operation S810. According to an embodiment, the preset reference value may correspond to a voltage level that is determined as logic high.

After the voltage level of the data signal DQ is calibrated, the memory device 10 may compare the voltage level of the data signal DQ with the preset reference value in operation S820. For example, the memory device 10 may perform a feedback operation with respect to the voltage level calibration. When the voltage level of the data signal DQ is not completely calibrated, the memory device 10 may newly calibrate the voltage level of the data signal DQ.

According to an embodiment, the memory device 10 may determine whether the voltage level of the data signal DQ is equal to the preset reference value in operation S830.

According to an embodiment, the memory device 10 may compare the voltage level of the data signal DQ with the preset reference value. For example, the memory device 10 may receive the preset reference value as a set value and determine whether the voltage level of the data signal DQ is equal to the preset reference value.

When it is determined that the voltage level of the data signal DQ is not equal to the preset reference value, the memory device 10 may perform calibration on the voltage of the data signal DQ based on a preset impedance value in operation S840.

For example, the memory device 10 may receive the data signal DQ and calibrate the voltage level of the data signal DQ based on the preset impedance value. For example, the memory device 10 may perform voltage level drop calibration on the data signal DQ based on impedance such that the voltage level of the data signal DQ has the preset reference value (e.g., VIH). For example, the memory device 10 may perform voltage level rise calibration on the data signal DQ based on the impedance such that the voltage level of the data signal DQ has the preset reference value (e.g., VIH).

Otherwise, when it is determined that the voltage level of the data signal DQ is equal to the preset reference value, the memory device 10 may stop the ZQ calibration in operation S850. According to an embodiment, the ZQ calibration may include an operation of calibrating an offset of the data signal DQ with respect to the preset reference value by calibrating the voltage level of the data signal DQ.

FIG. 9 is a flowchart of an operation of generating a code having voltage level information of a data signal based on an impedance value in an operating method of the memory device 10, according to an embodiment.

Referring to FIGS. 1, 2, and 9, according to an embodiment, the memory device 10 may calibrate the voltage level of the data signal DQ in operation S910.

According to an embodiment, the memory device 10 may compare the voltage level of the data signal DQ with a preset reference voltage level and calibrate the voltage level of the data signal DQ such that the difference between the voltage level of the data signal DQ and the reference voltage level has a preset reference value. According to an embodiment, the reference voltage level and the preset reference value may be determined when the memory device 10 is manufactured. For example, when the difference between the voltage level of the data signal DQ and the reference voltage level is greater than the preset reference value, the memory device 10 may determine that offset calibration of the voltage level of the data signal DQ is required and may calibrate the voltage level of the data signal DQ such that the difference between the voltage level of the data signal DQ and the reference voltage level has the preset reference value.

After the voltage level of the data signal DQ is calibrated, the loop circuit 220 of the memory device 10 may receive the data signal DQ through an input pad in operation S920.

For example, the input pad may receive the data signal DQ output from the comparator 221 in FIG. 3. According to an embodiment, the data signal DQ may be output from the comparator 221 when the data signal DQ has a voltage level that is greater than the preset reference value VIH. For example, when the voltage level of the data signal DQ has a value that is greater than the preset reference value, the comparator 221 of the memory device 10 may output the data signal DQ to the counter circuit 222 and the input pad of the counter circuit 222 may receive the data signal DQ so that calibration may be performed on the voltage level of the data signal DQ.

According to an embodiment, the memory device 10 may store the preset impedance value in operation S930.

According to an embodiment, the memory device 10 may store the preset impedance value and calibrate the voltage level of the data signal DQ. For example, the memory device 10 may receive the data signal DQ and calibrate the voltage level of the data signal DQ based on the preset impedance value. For example, the memory device 10 may perform voltage level drop calibration on the data signal DQ based on impedance such that the voltage level of the data signal DQ has the preset reference value VIH. For example, the memory device 10 may perform voltage level rise calibration on the data signal DQ based on the impedance such that the voltage level of the data signal DQ has the preset reference value VIH.

According to an embodiment, the driver 222c (FIG. 5) of the memory device 10 may transmit a code, which has voltage information of the data signal DQ that has been calibrated based on the preset impedance value, to the comparator 221 in operation S940.

For example, the driver 222c of the memory device 10 may generate the code, which includes the voltage information of the data signal DQ of which the voltage level has been calibrated, and transmit the code to the comparator 221, thereby allowing the comparator 221 to determine whether to perform second calibration on the data signal DQ. For example, when the voltage information included in the code is information indicating that the voltage level calibration of the data signal DQ has not been completely performed, the memory device 10 may newly calibrate the voltage level of the data signal DQ. In other words, when the difference between the voltage level of the data signal DQ and the reference voltage level is not equal to the preset reference value VIH after first calibration is performed on the voltage level of the data signal DQ, the memory device 10 may perform second calibration on the voltage level of the data signal DQ.

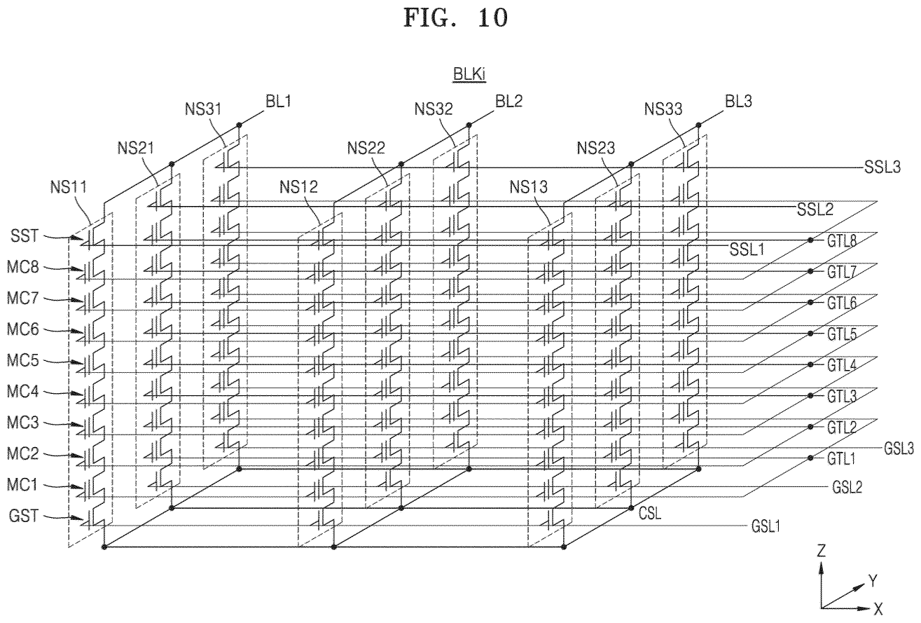

FIGS. 10 to 12 are diagrams illustrating a three-dimensional (3D) vertical NAND (VNAND) structure applicable to the memory device 10, according to an embodiment.

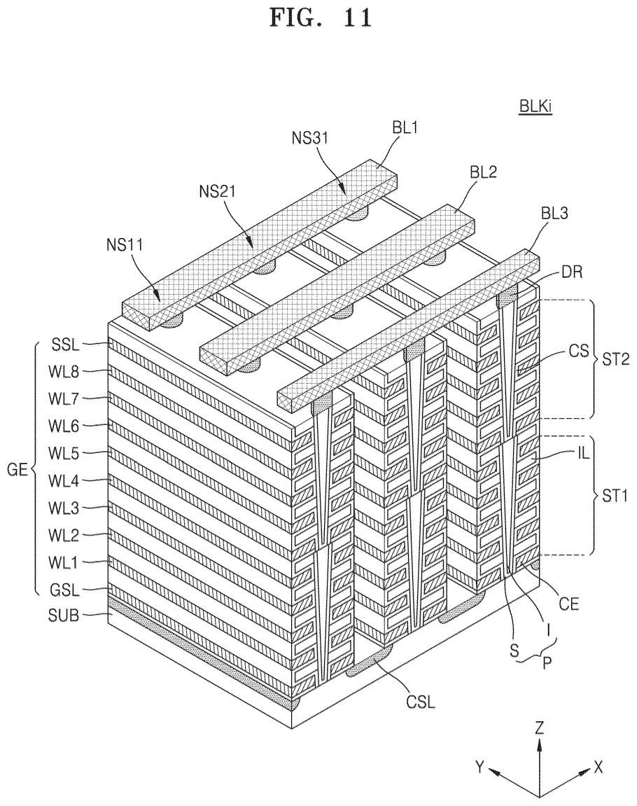

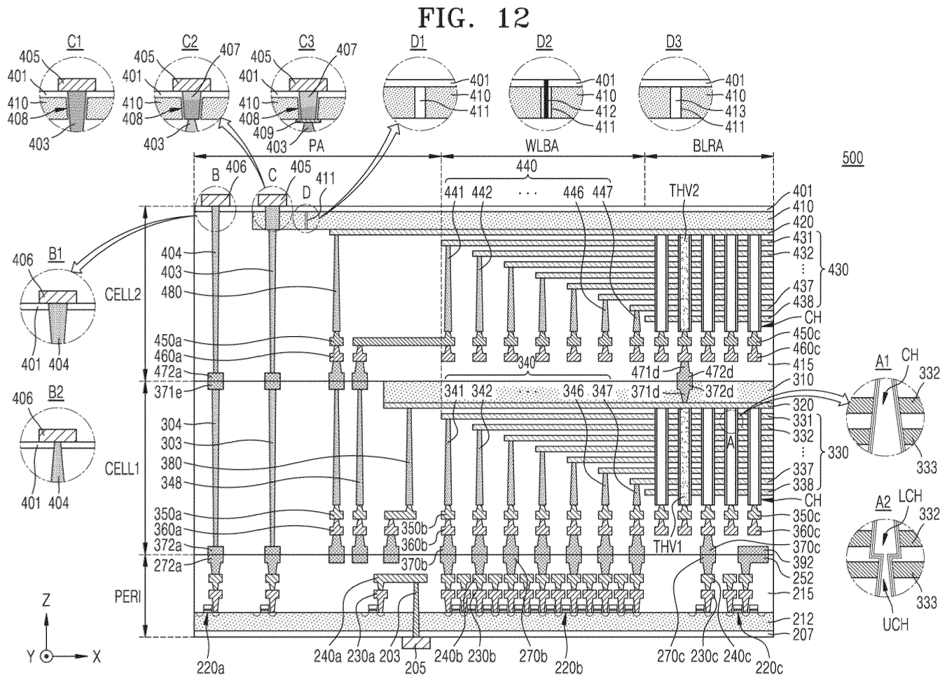

First non-volatile memory applicable to the memory device 10 may include a plurality of memory blocks. FIGS. 10 and 11 are diagrams illustrating the structure of a memory block BLKi among the memory blocks. FIG. 12 is a diagram illustrating an example implementation of a storage area (200 in FIG. 1) including non-volatile memory.

Referring to FIG. 10, the memory block BLKi may include memory NAND strings NS11 to NS33 connected between bit lines BL1, BL2, and BL3 and a common source line CSL. Each of the memory NAND strings NS11 to NS33 may include a string select transistor SST, a plurality of memory cells MC1 to MC8, and a ground select transistor GST. For simplicity of the drawings, it is illustrated in FIG. 10 that each of the memory NAND strings NS11 to NS33 includes eight memory cells MC1 to MC8, but embodiments are not necessarily limited thereto.

The string select transistor SST may be connected to its corresponding one among string selection lines SSL1 to SSL3. Each of the memory cells MC1 to MC8 may be connected to its corresponding one among gate lines GTL1 to GTL8. The gate lines GTL1 to GTL8 may correspond to word lines. Some of the gate lines GTL1 to GTL8 may correspond to dummy word lines. The ground select transistor GST may be connected to its corresponding one among ground select lines GSL1, GSL2, and GSL3. The string select transistor SST may be connected to its corresponding one among the lines BL1, BL2, and BL3, and the ground select transistor GST may be connected to the common source line CSL.

Gate lines (e.g., GTL1) at the same height may be connected in common to one another, and the ground select lines GSL1, GSL2, and GSL3 and the string select lines SSL1, SSL2, and SSL3 may be separated from one another. Although the memory block BLKi are connected to the eight gate lines GTL1 to GTL8 and three lines BL1, BL2, and BL3 in FIG. 10, embodiments are not limited thereto.

Referring further to FIG. 11, the memory block BLKi may be formed in a vertical direction with respect to a substrate SUB. Memory cells forming the memory NAND strings NS11 to NS33 may be stacked on a plurality of semiconductor layers.

The common source line CSL extends in a first direction (a Y direction) on the substrate SUB. In a region of the substrate SUB between two adjacent common source lines CSL, insulating layers IL may extend in the first direction (the Y direction) and may be sequentially provided in a third direction (a Z direction). The insulating layers IL may be separated from each other by a certain distance in the third direction (the Z direction). In the region of the substrate SUB between two adjacent common source lines CSL, pillars P may be sequentially arranged in the first direction (the Y direction) and may penetrate the insulating layers IL in the third direction (the Z direction). The pillars P may penetrate the insulating layers IL and may be in contact with the substrate SUB. A surface layer S of each pillar P may include a silicon material doped with a first conductivity type and may function as a channel region.

An inner layer I of each pillar P may include an insulating material such as silicon oxide or an air gap. In the region between two adjacent common source lines CSL, a charge storage layer CS may be provided along the exposed surfaces of the insulating layers IL, the pillars P, and the substrate SUB. The charge storage layer CS may include a gate insulating layer (or referred to as a tunneling insulating layer), a charge trap layer, and a blocking insulating layer. In the region between two adjacent common source lines CSL, gate electrodes GE, such as a ground select line GSL, a string select line SSL, and word lines WL1 to WL8, may be provided on an exposed surface of the charge storage layer CS. Drains or drain contacts DR may be respectively provided on the pillars P. The bit lines BL1 to BL3 may extend on the drain contacts DR in a second direction (an X direction) and may be separated from each other by a certain distance in the first direction (the Y direction).

As shown in FIG. 11, each of the memory NAND strings NS11 to NS33 may have a stack structure of a first memory stack ST1 and a second memory stack ST2. The first memory stack ST1 may be connected to the common source line CSL. The second memory stack ST2 may be connected to the bit lines BL1 to BL3. The first memory stack ST1 and the second memory stack ST2 may be stacked so as to share a channel hole.

FIG. 12 is a cross sectional view of a memory device 500 having a bonding VNAND (B-VNAND) structure, according to an embodiment.

FIG. 12 is a diagram illustrating the memory device 500 according to an embodiment.

Referring to FIG. 12, the memory device 500 may have a chip-to-chip (C2C) structure. Here, the C2C structure may refer to a structure formed by manufacturing at least one upper chip including a cell region CELL, manufacturing a lower chip including a peripheral circuit region PERI, and then connecting the at least one upper chip to the lower chip in a bonding manner. For example, the bonding manner may include a method of electrically or physically connecting a bonding metal pattern formed on an uppermost metal layer of the upper chip to a bonding metal pattern formed on an uppermost metal layer of the lower chip. For example, when the bonding metal patterns include copper (Cu), the bonding manner may be Cu—Cu bonding. As another example, the bonding metal patterns may include aluminum (Al) or tungsten (W).

The memory device 500 may include at least one upper chip including a cell region. For example, the memory device 500 of FIG. 12 may include two upper chips. However, this is just an example, and the number of upper chips is not limited thereto. When the memory device 500 includes two upper chips, a first upper chip including a first cell region CELL1, a second upper chip including a second cell region CELL2, and a lower chip including the peripheral circuit region PERI may be separately manufactured and then connected to one another by a bonding manner such that the memory device 500 may be manufactured. The first upper chip may be reversed and connected to the lower chip by a boning manner, and the second upper chip may also be reversed and connected to the first upper chip by a bonding manner. In the description below, the upper and lower portions of each of the first and second upper chips are defined based on before the reverse of the first and second upper chips. In other words, in FIG. 12, the upper portion of the lower chip is defined based on a +Z-axis direction, and the upper portion of each of the first and second upper chips is defined based on a −Z-axis direction. However, this is just an example, and only one of the first and second upper chips may be reversed and connected to the lower chip or the first upper chip by a bonding manner.

Each of the peripheral circuit region PERI and the first and second cell regions CELL1 and CELL2 of the memory device 500 may include an external pad bonding area PA, a word line bonding area WLBA, and a bit line bonding area BLBA.

The peripheral circuit region PERI may include a first substrate 212 and a plurality of circuit elements 220a, 220b, and 220c formed on the first substrate 212. An interlayer insulating layer 215 including at least one insulating layers may be on the circuit elements 220a, 220b, and 220c, and a plurality of metal interconnect lines connecting the circuit elements 220a, 220b, and 220c to one another may be in the interlayer insulating layer 215. For example, the metal interconnect lines may include first metal interconnect lines 230a, 230b, and 230c respectively connected to the plurality of circuit elements 220a, 220b, and 220c, and second metal interconnect lines 240a, 240b, and 240c formed on the first metal interconnect lines 230a, 230b, and 230c. The metal interconnect lines may include at least one conductive material. For example, the first metal interconnect lines 230a, 230b, and 230c may include tungsten having relatively high electrical resistivity, and the second metal interconnect lines 240a, 240b, and 240c may include copper having relatively low electrical resistivity.

Although the first metal interconnect lines 230a, 230b, and 230c and the second metal interconnect lines 240a, 240b, and 240c are shown and described in FIG. 12, embodiments are not limited thereto. One or more metal interconnect lines may be further formed on the second metal interconnect lines 240a, 240b, and 240c. In this case, the second metal interconnect lines 240a, 240b, and 240c may include aluminum. At least a portion of the one or more metal interconnect lines formed on the second metal interconnect lines 240a, 240b, and 240c may include copper or the like, which has a lower electrical resistivity than aluminum included in the second metal interconnect lines 240a, 240b, and 240c.

The interlayer insulating layer 215 may be on the first substrate 212 and include an insulating material, such as silicon oxide, silicon nitride, or the like.

Each of the first and second cell regions CELL1 and CELL2 may include at least one memory block. The first cell region CELL1 may include a second substrate 310 and a common source line 320. On the second substrate 310, a plurality of word lines 331 to 338 (i.e., 330) may be stacked in a direction (the Z-axis direction), perpendicular to the top surface of the second substrate 310. String select lines may be on the word lines 330, and a ground select line may be below the word lines 330. The word lines 330 may be between the string select lines and the ground select line. Similarly, the second cell region CELL2 may include a third substrate 410 and a common source line 420, and a plurality of word lines 431 to 438 (i.e., 430) may be stacked in the direction (the Z-axis direction), perpendicular to the top surface of the third substrate 410. The second substrate 310 and the third substrate 410 may include various materials. For example, the second substrate 310 and the third substrate 410 may include a silicon substrate, a silicon-germanium substrate, a germanium substrate, or a substrate having an epitaxial layer grown on a monocrystalline silicon substrate. A plurality of channel structures CH may be formed in each of the first and second cell regions CELL1 and CELL2.

In an embodiment, as shown in A1, a channel structure CH may be in the bit line bonding area BLBA and may extend in a direction, perpendicular to the top surface of the second substrate 310, and penetrate the word lines 330, the string select lines, and the ground select line. The channel structure CH may include a data storage layer, a channel layer, a buried insulating layer, and the like. The channel layer may be electrically connected to a first metal interconnect line 350c and a second metal interconnect line 360c in the bit line bonding area BLBA. For example, the second metal interconnect line 360c may be a bit line 360c and connected to the first metal interconnect line 350c through the channel structure CH. The bit line 360c may extend in a first direction (a Y-axis direction), parallel to the top surface of the second substrate 310.

In an embodiment, as shown in A2, the channel structure CH may include a lower channel LCH and an upper channel UCH connected to the lower channel LCH. For example, the channel structure may be formed by a process for the lower channel LCH and a process for the upper channel UCH. The lower channel LCH may extend in a direction perpendicular to the top surface of the second substrate 310 and pass through the common source line 320 and lower word lines (e.g., 331 and 332) The lower channel LCH may include a data storage layer, a channel layer, a buried insulating layer, and the like and may be connected to the upper channel UCH. The upper channel UCH may pass through upper word lines (e.g., 333 to 338). The upper channel UCH may include a data storage layer, a channel layer, a buried insulating layer, and the like. The channel layer of the upper channel UCH may be electrically connected to the first metal interconnect line 350c and the second metal interconnect line 360c. As the length of a channel increases, it may be hard to form a channel having a uniform width for the reason of processes. According to an embodiment, because the lower channel LCH and the upper channel UCH are formed by sequential processes, the memory device 500 may include a channel having increased width uniformity.

As shown in A2, when the channel structure CH includes the lower channel LCH and the upper channel UCH, a word line around the boundary between the lower channel LCH and the upper channel UCH may correspond to a dummy word line. For example, the word lines 332 and 333 around the boundary between the lower channel LCH and the upper channel UCH may correspond to dummy word lines. In this case, data may not be stored in memory cells connected to the dummy word lines. The number of pages corresponding to memory cells connected to dummy word lines may be less than the number of pages corresponding to memory cells connected to normal word lines. A voltage level applied to a dummy word line may be different from a voltage level applied to a normal word line, and accordingly, the influence of the non-uniform width of the lower and upper channels LCH and UCH on the operation of a memory device may decrease.

It is illustrated in A2 that the number of lower word lines (331 and 332) penetrated by the lower channel LCH is less than the number of upper word lines (333 to 338) penetrated by the upper channel UCH. However, it is just an example, and the disclosure is not limited thereto. As another example, the number of lower word lines penetrated by the lower channel LCH may be greater than or equal to the number of upper word lines penetrated by the upper channel UCH. The structure and connection of the channel structure CH in the first cell region CELL1, which have been described above, may also be applied to channel structures CH in the second cell region CELL2.

In the bit line bonding area BLBA, a first through electrode THV1 and a second through electrode THV2 may be respectively in the first and second cell regions CELL1 and CELL2. As shown in FIG. 12, the first through electrode THV1 may penetrate the common source line 320 and the word lines 330. However, this is just an example, and the first through electrode THV1 may further penetrate the second substrate 310. The first through electrode THV1 may include a conductive material. Alternatively, the first through electrode THV1 may include a conductive material surrounded by an insulating material. The shape and structure of the second through electrode THV2 may be the same as those of the first through electrode THV1.

In an embodiment, the first through electrode THV1 may be electrically connected to the second through electrode THV2 through a first through metal pattern 372d and a second through metal pattern 472d. The first through metal pattern 372d may be in the bottom of the first upper chip including the first cell region CELL1, and the second through metal pattern 472d may be in the top of the second upper chip including the second cell region CELL2. The first through electrode THV1 may be electrically connected to the first and second metal interconnect lines 350c and 360c. A lower via 371d may be between the first through electrode THV1 and the first through metal pattern 372d, and an upper via 471d may be between the second through electrode THV2 and the second through metal pattern 472d. The first through metal pattern 372d may be connected to the second through metal pattern 472d by a bonding manner.

In the bit line bonding area BLBA, an upper metal pattern 252 may be formed in an uppermost metal layer of the peripheral circuit region PERI, and an upper metal pattern 392, which has the same shape as the upper metal pattern 252, may be formed in an uppermost metal layer of the first cell region CELL. The upper metal pattern 392 of the first cell region CELL may be electrically connected to the upper metal pattern 252 of the peripheral circuit region PERI by a bonding manner. In the bit line bonding area BLBA, the bit line 360c may be electrically connected to a page buffer included in the peripheral circuit region PERI. For example, some of the circuit elements 220c of the peripheral circuit region PERI may provide a page buffer, and the bit line 360c may be electrically connected to the circuit elements 220c, which provide the page buffer, through an upper bonding metal 370c of the first cell region CELL and an upper bonding metal 270c of the peripheral circuit region PERI.

In the word line bonding area WLBA, the word lines 330 of the first cell region CELL may extend in a second direction (an X-axis direction), parallel with the top surface of the second substrate 310, and may be connected to a plurality of cell contact plugs 341 to 347 (i.e., 340). A first metal interconnect line 350b and a second metal interconnect line 360b may be sequentially connected to an upper portion of each of the cell contact plugs 340 respectively connected to the word lines 330. In the word line bonding area WLBA, the cell contact plugs 340 may be connected to the peripheral circuit region PERI by an upper bonding metal 370b of the first cell region CELL1 and an upper bonding metal 270b of the peripheral circuit region PERI.

The cell contact plugs 340 may be electrically connected to a row decoder included in the peripheral circuit region PERI. For example, some of the circuit elements 220b of the peripheral circuit region PERI may provide the row decoder, and the cell contact plugs 340 may be electrically connected to the circuit elements 220b, which provide the row decoder, by the upper bonding metal 370b of the first cell region CELL1 and the upper bonding metal 270b of the peripheral circuit region PERI. In an embodiment, operating voltages of the circuit elements 220b providing the row decoder may be different from operating voltages of the circuit elements 220c providing the page buffer. For example, operating voltages of the circuit elements 220c providing the page buffer may be greater than operating voltages of the circuit elements 220b providing the row decoder.

Similarly, in the word line bonding area WLBA, the word lines 430 of the second cell region CELL2 may extend in the second direction (the X-axis direction), parallel with the top surface of the third substrate 410, and may be connected to a plurality of cell contact plugs 441 to 447 (i.e., 440). The cell contact plugs 440 may be connected to the peripheral circuit region PERI by an upper metal pattern of the second cell region CELL2, a lower metal pattern and an upper metal pattern of the first cell region CELL1, and the cell contact plug 348.

In the word line bonding area WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding manner. The upper bonding metals 370b and 270b may include aluminum, copper, or tungsten.

In the external pad bonding area PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by a bonding manner in the external pad bonding area PA. Similarly, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by a bonding manner.

Common source line contact plugs 380 and 480 may be in the external pad bonding area PA. The common source line contact plugs 380 and 480 may include a conductive material, such as metal, a metal compound, or doped polysilicon. The common source line contact plug 380 of the first cell region CELL1 may be electrically connected to the common source line 320, and the common source line contact plug 480 of the second cell region CELL2 may be electrically connected to the common source line 420. A first metal interconnect line 350a and a second metal interconnect line 360a may be sequentially stacked above the common source line contact plug 380 of the first cell region CELL1, and a first metal interconnect line 450a and a second metal interconnect line 460a may be sequentially stacked above the common source line contact plug 480 of the second cell region CELL2.

First to third input/output (I/O) pads 205, 405, and 406 may be in the external pad bonding area PA. Referring to FIG. 12, a lower insulating film 207 may cover the bottom surface of the first substrate 212, and the first I/O pad 205 may be formed on the lower insulating film 207. The first I/O pad 205 may be connected to at least one of the circuit elements 220a of the peripheral circuit region PERI by a first I/O contact plug 203 and may be separated from the first substrate 212 by the lower insulating film 207. A side insulating film may be between the first I/O contact plug 203 and the first substrate 212 and thus electrically separate the first I/O contact plug 203 and the first substrate 212.

An upper insulating film 401 may be on the third substrate 410 to cover the top surface of the third substrate 410. The second I/O pad 405 and/or the third I/O pad 406 may be on the upper insulating film 401. The second I/O pad 405 may be connected to at least one of the circuit elements 220a of the peripheral circuit region PERI by second I/O contact plugs 403 and 303, and the third I/O pad 406 may be connected to at least one of the circuit elements 220a of the peripheral circuit region PERI by third I/O contact plugs 404 and 304.

In an embodiment, the third substrate 410 may not be formed in a region, in which an I/O contact plug is arranged. For example, as shown in B, the third I/O contact plug 404 may be separated from the third substrate 410 in a direction parallel with the top surface of the third substrate 410 and may pass through an interlayer insulating layer 415 of the second cell region CELL2 to be connected to the third I/O pad 406. In this case, the third I/O contact plug 404 may be formed by various processes.

For example, as shown in B1, the third I/O contact plug 404 may extend in a third direction (e.g., the Z-axis direction) and have a diameter increasing toward the upper insulating film 401. In other words, while the diameter of the channel structure CH described with reference to A1 decreases toward the upper insulating film 401, the diameter of the third I/O contact plug 404 may increase toward the upper insulating film 401. For example, the third I/O contact plug 404 may be formed after the second cell region CELL2 is connected to the first cell region CELL1 by a bonding manner.

For example, as shown in B2, the third I/O contact plug 404 may extend in the third direction (e.g., the Z-axis direction) and have a diameter decreasing toward the upper insulating film 401. In other words, the diameter of the third I/O contact plug 404 may decrease toward the upper insulating film 401 like the diameter of the channel structure CH. For example, the third I/O contact plug 404 may be formed together with the cell contact plugs 440 before the second cell region CELL2 is connected to the first cell region CELL1 by a bonding manner.

In one or more embodiments, an I/O contact plug may overlap with the third substrate 410. For example, as shown in C, the second I/O contact plug 403 may pass through the interlayer insulating layer 415 of the second cell region CELL2 in the third direction (the Z-axis direction) and may be electrically connected to the second I/O pad 405 through the third substrate 410. In this case, a connection structure of the second I/O contact plug 403 and the second I/O pad 405 may be implemented in various manners.

For example, as shown in C1, an opening 408 may be formed through the third substrate 410, and the second I/O contact plug 403 may be directly connected to the second I/O pad 405 through the opening 408 formed in the third substrate 410. In this case, as shown in C1, the diameter of the second I/O contact plug 403 may increase toward the second I/O pad 405. However, this is just an example, and the diameter of the second I/O contact plug 403 may decrease toward the second I/O pad 405.

For example, as shown in C2, the opening 408 may be formed through the third substrate 410, and a contact 407 may be formed in the opening 408. An end of the contact 407 may be connected to the second I/O pad 405, and an opposite end of the contact 407 may be connected to the second I/O contact plug 403. Accordingly, the second I/O contact plug 403 may be electrically connected to the second I/O pad 405 by the contact 407 in the opening 408. In this case, as shown in C2, the diameter of the contact 407 may increase toward the second I/O pad 405, and the diameter of the second I/O contact plug 403 may decrease toward the second I/O pad 405. For example, the second I/O contact plug 403 may be formed together with the cell contact plugs 440 before the second cell region CELL2 is connected to the first cell region CELL1 by a bonding manner, and the contact 407 may be formed after the second cell region CELL2 is connected to the first cell region CELL1 by the bonding manner.

For example, as shown in C3, a stopper 409 may be further formed on the top surface of the opening 408 of the third substrate 410 compared to C2. The stopper 409 may include a metal interconnect line formed in the same layer as the common source line 420. However, this is just an example, and the stopper 409 may include a metal interconnect line formed in the same layer as at least one of the word lines 430. The second I/O contact plug 403 may be electrically connected to the second I/O pad 405 by the contact 407 and the stopper 409.

Similar to the second and third I/O contact plugs 403 and 404 of the second cell region CELL2, each of the second and third I/O contact plugs 303 and 304 of the first cell region CELL1 may have a diameter increasing or decreasing toward the lower metal pattern 371e.

According to embodiments, a slit 411 may be formed in the third substrate 410. For example, the slit 411 may be formed in a random position in the external pad bonding area PA. As shown in D, the slit 411 may be between the second I/O pad 405 and the cell contact plugs 440 in a plan view. However, this is just an example, and the second I/O pad 405 may be between the slit 411 and the cell contact plugs 440 in a plan view.

As shown in D1, the slit 411 may pass through the third substrate 410. For example, the slit 411 may be used to prevent the third substrate 410 from finely cracking when the opening 408 is formed. However, this is just an example, and the slit 411 may be formed to have a depth of about 60% to about 70% of the thickness of the third substrate 410.

As shown in D2, a conductive material 412 may be formed in the slit 411. For example, the conductive material 412 may be used to discharge leakage current, which is generated while circuit elements of the external pad bonding area PA are operating. In this case, the conductive material 412 may be connected to an external ground line.

As shown in D3, an insulating material 413 may be formed in the slit 411. For example, the insulating material 413 may be formed to electrically separate the second I/O pad 405 and the second I/O contact plug 403 in the external pad bonding area PA from the word line bonding area WLBA. When the insulating material 413 is formed in the slit 411, a voltage provided through the second I/O pad 405 may be prevented from influencing a metal layer on the third substrate 410 in the word line bonding area WLBA.

According to embodiments, the first to third I/O pads 205, 405, and 406 may be selectively formed. For example, the memory device 500 may include only the first I/O pad 205 above the first substrate 212, only the second I/O pad 405 above the third substrate 410, or only the third I/O pad 406 on the upper insulating film 401.

According to embodiments, at least one selected from the group consisting of the second substrate 310 of the first cell region CELL1 and the third substrate 410 of the second cell region CELL2 may be used as a sacrificial substrate and entirely or partially removed before or after a bonding process. An additional film may be stacked on a resultant structure after the sacrificial substrate is removed. For example, the second substrate 310 of the first cell region CELL1 may be removed before or after the bonding between the peripheral circuit region PERI and the first cell region CELL1, and an insulating film covering the top surface of the common source line 320 or a conductive film for connection to the common source line 320 may be formed. Similarly, the third substrate 410 of the second cell region CELL2 may be removed before or after the bonding between the first cell region CELL1 and the second cell region CELL2, and the upper insulating film 401 covering the top surface of the common source line 420 or a conductive film for connection to the common source line 420 may be formed.

While the disclosure has been particularly shown and described with reference to embodiments thereof, it will be understood that various changes in form and details may be made therein without departing from the spirit and scope of the following claims.

What is claimed is:

1. A memory device comprising:
a memory controller configured to generate a data signal;
a plurality of channels configured to transmit the data signal; and
a plurality of storage areas configured to receive the data signal,
wherein each of the plurality of storage areas comprises:
an input pin configured to receive the data signal; and
a loop circuit configured to:
compare a voltage level of the data signal with a preset reference voltage level, and
calibrate, based on a result of the comparison of the voltage level of the data signal and the preset reference voltage level, the voltage level of the data signal such that a difference between the voltage level of the data signal and the preset reference voltage level has a preset reference value,
wherein each of the plurality of storage areas are further configured to independently calibrate voltage levels of the data signal.

2. The memory device of claim 1,
wherein each channel of the plurality of channels corresponds to a storage area of the plurality of storage areas, and each of the plurality of storage areas comprises an input pin and a loop circuit,
wherein the memory controller is further configured to generate a plurality of data signals which include the data signal, and the plurality of channels is configured to transmit the plurality of data signals to the plurality of storage areas,
wherein each respective storage area of the plurality of storage areas is configured to receive, through the input pin of the respective storage area, a data signal of the plurality of data signals from the corresponding channel of the plurality of channels, and wherein the data signal received by the input pin of the respective storage area comprises a received data signal, and
wherein the loop circuit of each respective storage area of the plurality of storage areas is configured to:
compare a voltage level of the received data signal and the preset reference voltage level, and
calibrate, based on a result of the comparison of the voltage level of the received data signal and the preset reference voltage level, the voltage level of the received data signal such that a difference between the voltage level of the received data signal and the preset reference voltage level has the preset reference value.

3. The memory device of claim 1, wherein the loop circuit further comprises:
a comparator configured to compare the preset reference value and the voltage level of the data signal; and
a counter circuit configured to calibrate the voltage level of the data signal such that the difference between the voltage level of the data signal and the preset reference voltage level has the preset reference value.

4. The memory device of claim 3,
wherein the counter circuit comprises:
an input pad configured to receive the data signal;
an impedance storage unit configured to store a preset impedance value; and
a driver configured to transmit a code to the comparator,
wherein the voltage level of the data signal is calibrated based on the preset impedance value, and
wherein the code comprises voltage information of the calibrated data signal.

5. The memory device of claim 1, further comprising:
a plurality of channels including the channel; and
a plurality of storage areas including the storage area, wherein each channel of the plurality of channels corresponds to a storage area of the plurality of storage areas, and each of the plurality of storage areas comprises an input pin and a loop circuit,
wherein the data signal comprises a plurality of data signals, and the plurality of channels is configured to transmit the plurality of data signals to the plurality of storage areas,
wherein each respective storage area of the plurality of storage areas is configured to receive, through the input pin of the respective storage area, a data signal of the plurality of data signals from the corresponding channel of the plurality of channels, and wherein each data signal received by the input pin of a respective storage area respectively comprises a received data signal, and
wherein the loop circuit of each storage area of the plurality of storage areas comprises:
a comparator configured to compare the preset reference value and the voltage level of the received data signal; and
a counter circuit configured to calibrate the voltage level of the received data signal such that the difference between the voltage level of the received data signal and the preset reference voltage level has the preset reference value.

6. The memory device of claim 5,
wherein the counter circuit of each loop circuit of each respective storage area of the plurality of storage areas comprises:
an input pad configured to receive the received data signal;
an impedance storage unit configured to store a preset impedance value; and
a driver configured to transmit a code to the comparator of the loop circuit including the respective counter circuit,
wherein the voltage level of the received data signal is calibrated based on the preset impedance value, and
wherein the code comprises voltage information of the calibrated received data signal.

7. The memory device of claim 1, wherein the loop circuit is further configured to calibrate the voltage level of the data signal by matching the difference between the voltage level of the data signal and the preset reference voltage level to the preset reference value based on a reference voltage information signal received from the memory controller.

8. A method of operating a memory device, the method comprising:
generating, by a memory controller of the memory device, a data signal;
transmitting the data signal through a channel of the memory device; and
receiving, by a storage area of the memory device, the data signal,
wherein the receiving the data signal comprises:
comparing a voltage level of the data signal with a preset reference voltage level; and
calibrating, based on a result of the comparison of the voltage level of the data signal and the preset reference voltage level, the voltage level of the data signal such that a difference between the voltage level of the data signal and the preset reference voltage level has a preset reference value.

9. The method of claim 8, wherein the calibrating the voltage level of the data signal further comprises:
calibrating the voltage level of the data signal based on a preset impedance value.

10. The method of claim 9, wherein the calibrating the voltage level of the data signal further comprises:
receiving the data signal through an input pad of the storage area;
storing the preset impedance value by the storage area; and
transmitting a code from a driver of the memory device to a comparator of the memory device, wherein the code comprises voltage information of the calibrated data signal.

11. The method of claim 9, further comprising:
generating, by the memory controller, a plurality of data signals which include the data signal;
transmitting the plurality of data signals through a plurality of channels of the memory device, wherein the plurality of channels includes the channel; and
receiving, by each respective storage area of a plurality of storage areas of the memory device, a data signal of the plurality of data signals from a channel of the plurality of channels corresponding to the respective storage area, wherein each data signal received by a respective storage area comprises a received data signal,
wherein each received data signal is received by the respective storage area via an input pin of the respective storage area, and
wherein the receiving the plurality of data signals comprises, for each respective storage area of the plurality of storage areas:
comparing the voltage level of the received data signal with the preset reference voltage level; and
calibrating, based on a result of the comparison of the voltage level of the received data signal and the preset reference voltage level, the voltage level of the received data signal such that a difference between the voltage level of the received data signal and the preset reference voltage level has the preset reference value.

12. The method of claim 9,
wherein the storage area includes a loop circuit, the loop circuit including a comparator and a counter circuit, and
wherein the receiving the data signal further comprises:
receiving the data signal via an input pad of the counter circuit; and
transmitting, by a driver of the counter circuit, a code to the comparator, wherein the code comprises voltage information of the calibrated data signal.

13. The method of claim 8, wherein the calibrating the voltage level of the data signal further comprises matching the difference between the voltage level of the data signal and the preset reference voltage level to the preset reference value based on a reference voltage information signal received from the memory controller.

14. A memory device comprising:
a storage area, the storage area comprising:
an input pin configured to receive a data signal; and
a loop circuit configured to:
compare a voltage level of the data signal and a preset reference voltage level, and
calibrate, based on a result of the comparison of the voltage level of the data signal and the present reference voltage, the voltage level of the data signal such that a difference between the voltage level of the data signal and the preset reference voltage level has a preset reference value.

15. The memory device of claim 14, further comprising a plurality of storage areas including the storage area,
wherein each of the plurality of storage areas comprises an input pin and a loop circuit,
wherein each respective storage area of the plurality of storage areas is configured to receive a data signal from among a plurality of data signals through the input pin of the respective storage area, and wherein the data signal received by the input pin of the respective storage area comprises a received data signal, and
wherein the loop circuit of each respective storage area of the plurality of storage areas is configured to:
compare a voltage level of the received data signal and the preset reference voltage level, and
calibrate, based on a result of the comparison of the voltage level of the received data signal and the preset reference voltage level, the voltage level of the received data signal such that a difference between the voltage level of the received data signal and the preset reference voltage level has the preset reference value.

16. The memory device of claim 14, wherein the loop circuit comprises:
a comparator configured to compare the preset reference value and the voltage level of the data signal; and
a counter circuit configured to calibrate the voltage level of the data signal such that the difference between the voltage level of the data signal and the preset reference voltage level has the preset reference value.

17. The memory device of claim 16,
wherein the counter circuit comprises:
an input pad configured to receive the data signal;
an impedance storage unit configured to store a preset impedance value; and
a driver configured to transmit a code to the comparator,
wherein the voltage level of the data signal is calibrated based on the preset impedance value, and
wherein the code comprises voltage information of the calibrated data signal.

18. The memory device of claim 15, wherein the loop circuit of each storage area of the plurality of storage areas comprises:
a comparator configured to compare the preset reference value and the voltage level of the received data signal; and
a counter circuit configured to calibrate the voltage level of the received data signal such that the difference between the voltage level of the received data signal and the preset reference voltage level has the preset reference value.

19. The memory device of claim 18,
wherein the counter circuit of the loop circuit of each respective storage area of the plurality of storage areas comprises:
an input pad configured to receive the received data signal;
an impedance storage unit configured to store a preset impedance value; and
a driver configured to transmit a code to the comparator of the respective storage area,
wherein the voltage level of the received data signal is calibrated based on the preset impedance value, and
wherein the code comprises voltage information of the calibrated received data signal.

20. The memory device of claim 14, wherein the loop circuit is further configured to perform calibration by matching the difference between the voltage level of the data signal and the preset reference voltage level to the preset reference value based on a reference voltage information signal.
